(19) United States
(12) Patent Application Publication
(10) Pub. No.: US 2005/0082547 A1
(43) Pub. Date: Apr. 21, 2005

(54) Light emitting device having a transparent conducting layer

(76) Inventors: Pan-Tzu Chang, Dashi (TW); Ying-Che Sung, Dashi (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/914,207

(22) Filed: Aug. 10, 2004

(30) Foreign Application Priority Data
Oct. 16, 2003 (TW) 092218382

(51) Int. Cl. H01L 27/15

(52) U.S. Cl. 257/79

(57) ABSTRACT

A light emitting device includes a substrate, an n-type semiconductor layer and a p-type semiconductor layer formed on the surface of the substrate, an n-electrode formed on the n-type semiconductor layer, an evenly spread ohmic contact layer formed on the p-type semiconductor layer in the form of evenly spread dots, a net, or a honeycomb, and a transparent conducting layer selected from ITO or ZnO and covered on the ohmic contact layer.

### BACKGROUND OF THE INVENTION

a. Field of the invention:

The present invention relates to light emitting devices and, more particularly, to such a light emitting device, which comprises an ohmic contact layer formed on the p-type semiconductor layer in the form of evenly spread dots, a net, or a honeycomb, and a transparent conducting layer selected from ITO or ZnO and covered on the ohmic contact layer.

b. Description of the Related Art:

Compound semiconductors of GaN series III-V series including GaN, GaAlN, InGaN, and InAlGaN are commonly used for making blue Green UV LEDs (light emitting diodes). A LED generally comprises a substrate, and an n-type GaN series semiconductor layer and a p-type semiconductor layer formed on the substrate. P-n bonding type GaN III-V series compound semiconductor LEDs have limitations on fabrication. In compound semiconductor layers, the top layer is the p-type compound semiconductor layer. Further, sapphire substrate is commonly used for making blue LEDs. However, because sapphire is electrically insulative, p-electrode and n-electrode must be respectively directly connected to the p-type semiconductor layer and the n-type semiconductor layer.

FIGS. 1 and 2 show a light emitting diode designed by Nichia Chemical Industries, Ltd., Japan, and issued under U.S. Pat. Nos.: 5,563,422 and 5,652,434. This structure of LED 10 comprises a substrate 11, an n-type semiconductor layer 12 and a p-type semiconductor layer 13 formed on the substrate 11, a first electrode 14 formed on the n-type semiconductor layer 12, and a second electrode 15 formed on the p-type semiconductor layer 13. The second electrode 15 is selected from Ni or Au, and forms with the p-type semiconductor layer 13 an ohmic contact. According to this design, the electrode at the p-type semiconductor layer is formed of NiAu and covered on the whole surface of the p-type semiconductor layer. Because the transmittancy of this semitransparent conducting structure is simply within 50%˜80%, the intensity of light of this design of LED is still not strong enough.

### SUMMARY OF THE INVENTION

The present invention has been accomplished under the circumstances in view. It is one object of the present invention to provide a light-emitting device, which eliminates the low transmittancy problem of the prior art designs. It is another object of the present invention to provide a light emitting device, which uses a specially designed ohmic contact layer and a transparent conducting layer to enhance electric conductivity and transmittancy. According to one aspect of the present invention, the light emitting device comprises a substrate; an n-type semiconductor layer and a p-type semiconductor layer formed on the surface of the substrate; an n-electrode formed on the n-type semiconductor layer; wherein an evenly spread ohmic contact layer is formed on the p-type semiconductor layer in one of the forms of evenly spread dots, a net, and a honeycomb, and a transparent conducting layer is covered on the ohmic contact layer. According to another aspect of the present invention, the ohmic contact layer is selected from one of a group of materials including Pd, Ag, PdAg, Rh, NiAu, NiCuAu, and NiO. According to still another aspect of the present invention, the transparent conducting layer is selected from one of the materials of ITO and ZnO.

### BRIEF DESCRIPTION OF THE DRAWINGS

FIG. 1 is a top view of a light-emitting device according to the prior art.

FIG. 2 is a sectional view taken along line 2-2 of FIG. 1.

FIG. 3 is a top view of a light-emitting device according to the present invention.

FIG. 4 is a sectional view taken along line 4-4 of FIG. 3.

FIG. 5 is a top view of an alternate form of the light-emitting device according to the present invention.

FIG. 6 is a top view of another alternate form of the light-emitting device according to the present invention.

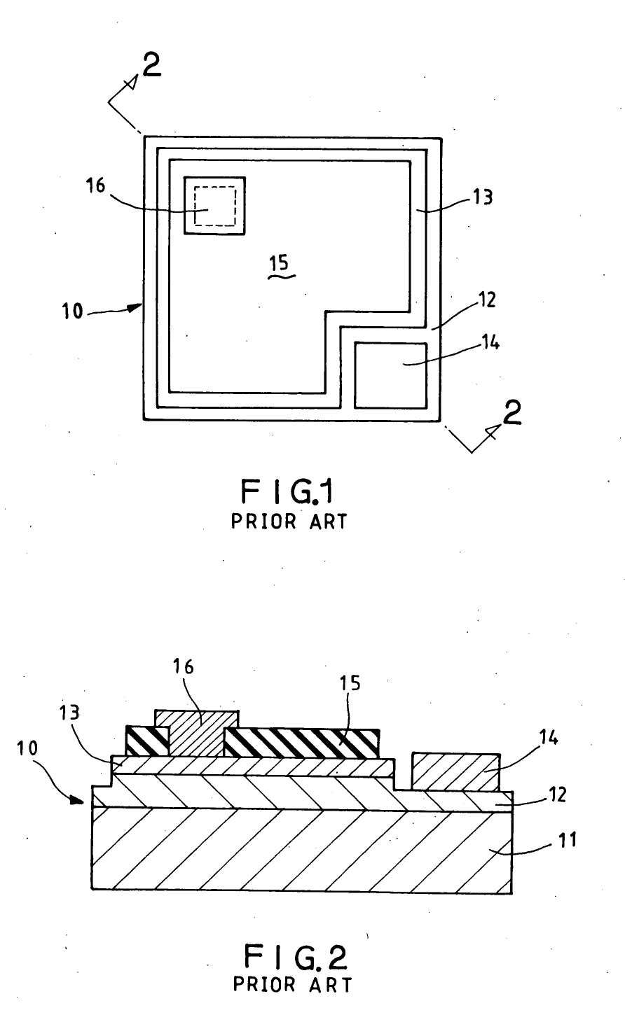

### DETAILED DESCRIPTION OF THE PREFERRED EMBODIMENTS

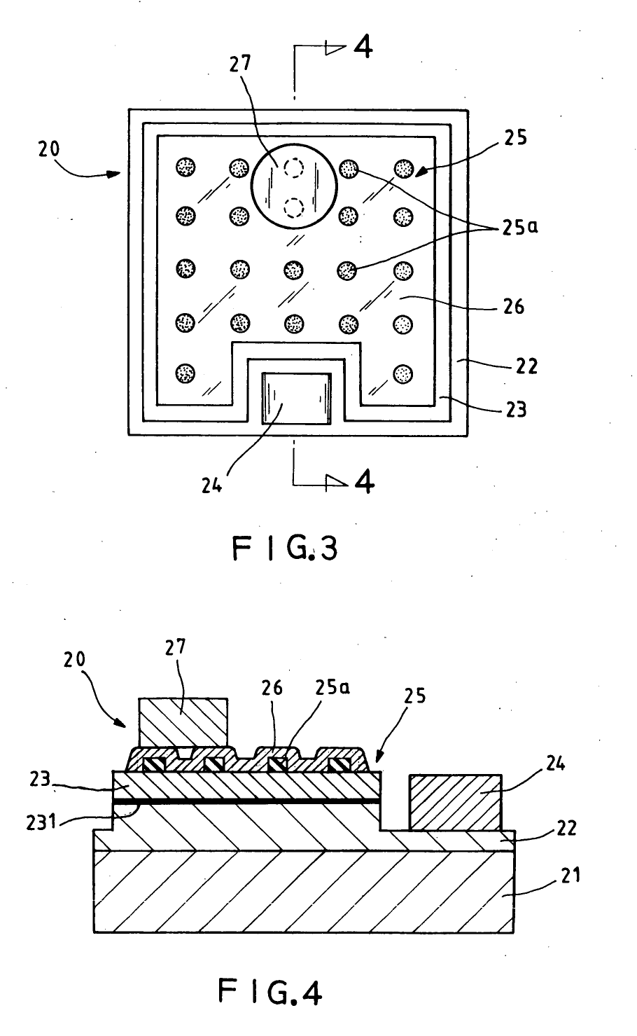

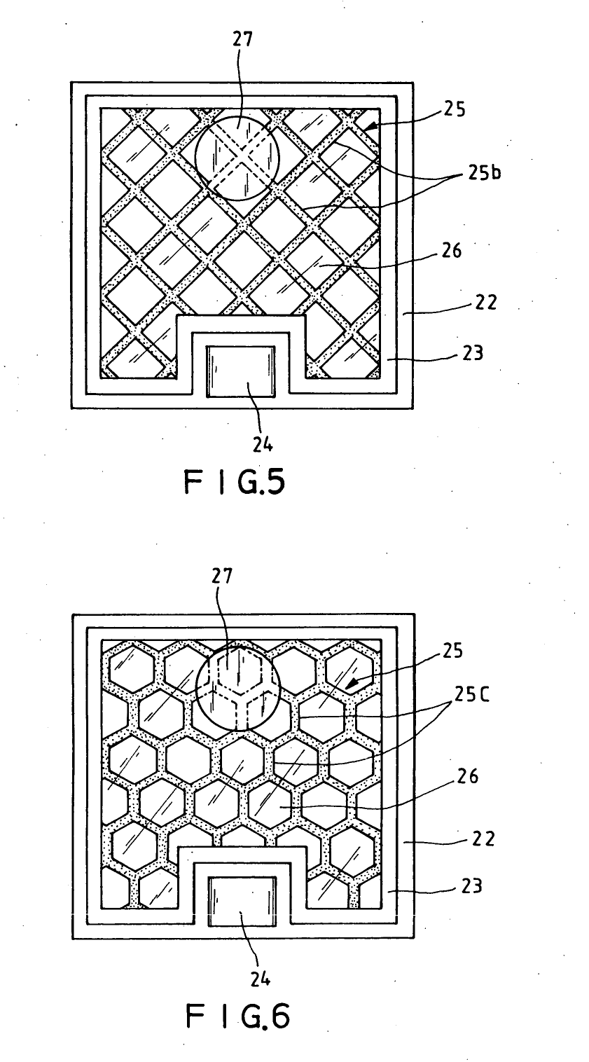

Referring to FIGS. 3 and 4, a light emitting device 20 is shown comprising a substrate 21, which can be, for example, a sapphire substrate, a n-type semiconductor layer 22 formed of n-type GaN III-V compound of thickness within about 0.5 μm˜10 μm on the surface of the substrate 21, an active layer 231 and a p-type semiconductor layer 23 of thickness within about 0.1 μm˜5 μm formed on the surface of the n-type semiconductor layer 22, an n-type electrode 24 formed on the surface of the n-type semiconductor layer 22 outside the p-type semiconductor layer 23 after the application of an etching process to the n-type semiconductor layer 22 and p-type semiconductor layer 23 of, an evenly spread ohmic contact layer 25 selected from Pd, Ag, PdAg, Rh, NiAu NiCuAu, or NiO, and formed on the surface of the p-type semiconductor layer 23, a transparent conducting layer 26 covered on the ohmic contact layer 25, and a p-type electrode 27 formed on a part of the p-type semiconductor layer 23. Unlike the prior art design of covering NiAu bimetal over the whole surface of the semitransparent conducting layer of p-type semiconductor layer, the ohmic contact layer 25 can be evenly spread dots 25a of Pd, Ag, PdAg, Rh, NiAu, NiCuAu, or NiO. Alternatively, the ohmic contact layer 25 can be a net 25b of Pd, Ag, PdAg, Rh, NiAu, NiCuAu, or NiO (see FIG. 5), or a honeycomb 25c of Pd, Ag, PdAg, Rh, NiAu, NiCuAu or NiO (see FIG. 6). For high performance, current spreading in p-layer is important. Normally, the ohmic contact in a light-emitting device is for wiring. Electric current passes downwards from the top through the p-type semiconductor layer 23 to the active layer 231 so as to produce light. However, if the resistance of the p-type layer is very high, electric current will not be evenly distributed, but will be gathered under the electrode and blocked by the metal contact and further absorbed by the active layer.

The dots 25a, net 25b, or honeycomb 25c type ohmic contact layer 25 improves spreading of electric current. However, this simple measure still cannot greatly enhance lighting efficiency. Therefore, the invention covers the transparent conducting layer 26 over the ohmic contact layer 25 to enhance the spreading of electric current. The transparent conducting layer 26 can be selected from ITO (Indium Tin Oxide) or ZnO (Zinc Oxide), and coated on the p-type semiconductor layer 23 by sputtering or evaporation. For the advantages of good electric conductivity and over 90% transmittancy, ITO (Indium Tin Oxide) and ZnO (Zinc Oxide) can be selected for the transparent conducting layer 26. Although direct electric contact between ITO/ZnO and the p-type semiconductor layer 23 is not easy, under the support of dots 25a, net 25b, or honeycomb 25c type ohmic contact layer 25, electric conductivity and transmittancy are greatly enhanced.

Although particular embodiments of the present invention have been shown and described, it will be understood that various modifications and changes could be made thereunto without departing from the spirit and scope of the invention disclosed.

1. A light emitting device comprising:
a substrate;
an n-type semiconductor layer and an active layer, and a p-type semiconductor layer formed on the surface of said substrate;
an n-electrode formed on said n-type semiconductor layer;
wherein an evenly spread ohmic contact layer is formed on said p-type semiconductor layer in one of the forms of evenly spread dots, a net, and a honeycomb, and a transparent conducting layer is covered on said ohmic contact layer.

2. The light emitting device as claimed in claim 1, wherein said ohmic contact layer is selected from one of a group of materials including Pd, Ag, PdAg, Rh, NiAu, NiCuAu, and NiO.

3. The light emitting device as claimed in claim 1, wherein said transparent conducting layer is selected from one of the materials of ITO and ZnO.

4. The light emitting device as claimed in claim 1, further comprising a p-electrode formed on a part of said p-type semiconductor layer.
